(19) United States
(12) Patent Application Publication
(10) Pub. No.: US 2011/0019433 A1
(43) Pub. Date: Jan. 27, 2011

(54) LED LIGHTING DEVICE

(75) Inventor: David Dussault, Neutraubling (DE)

Correspondence Address: Viering, Jentschura & Partner - OSR, 3770 Highland Ave., Suite 203, Manhattan Beach, CA, 90266, US

(73) Assignee: OSRAM GESELLSCHAFT MIT BESCHRAENKTER HAFTUNG, Muenchen (DE)

(21) Appl. No.: 12/933,088

(22) PCT Filed: Mar. 17, 2008
(86) PCT No.: PCT/EP08/02101

§ 371 Date: Sep. 17, 2010

(51) Int. Cl. F21V 7/04; H01L 33/00

(52) U.S. Cl. 362/555; 257/88; 257/89; 257/E33.001

(57) ABSTRACT

A light-emitting diode lighting device may include a plurality of light-emitting diodes fastened on a flexible substrate, the flexible substrate being applied on a surface of a rod-shaped carrier.

The invention relates to an LED lighting device with a plurality of light-emitting diodes, LEDs, fastened on a flexible substrate, a set of a plurality of such LED lighting devices and a corresponding LED luminaire.

Until now it has been known to fasten a flexible printed circuit board (“flexboard”), which is equipped with LEDs, flat on a carrier and then to align the carrier in the desired emission direction. For this purpose, flexible tapes (“flextapes”), which are equipped in particular with LEDs, can be divided and are equipped with a self-adhesive reverse are known, for example the LINEARlight Flex series by Osram, for example LM10A with LEDs, which have an emission direction for the LEDs which is directed perpendicular to the fastening surface, or LM11A with LEDs which have an emission direction for the LEDs which is directed parallel to the fastening surface. Further flexible tapes equipped with LEDs include particularly powerful LEDs (LM10P series by Osram) and flexible tapes with multicolored LEDs (LM10L series of Osram). However, this quickly becomes complex in design terms in the case of lighting devices intended to emit light with a relatively large solid angle.

It is therefore the object of the present invention to provide a simple and inexpensive possibility for the more homogeneous light emission with a relatively large solid angle, in particular with a peripheral solid angle of 360°.

This object is achieved by means of an LED lighting device as claimed in claim 1, a set of a plurality of LED lighting devices as claimed in claim 20 and an LED luminaire as claimed in claim 23. Advantageous configurations are given in particular in the dependent claims.

The LED lighting device is equipped with a plurality of light-emitting diodes, LEDs, fastened on a flexible substrate. The flexible substrate in turn, is applied to a surface of a rod-shaped carrier.

As a result, it is possible to achieve an emission for the LEDs which is peripheral with respect to the longitudinal axis of up to 360° by virtue of a simple and inexpensive configuration of the carrier, while the use of the flexible substrate results in a solution for fastening the LEDs on a substrate which is inexpensive and simple in terms of production.

The flexible substrate can be, for example, in the form of a flexboard or “flexfilm” or “flextape”, for example, on the basis of polyimide film substrates. In particular, the flextapes of the series LM-XX by Osram are suitable for this purpose. Typically, the substrate has electrical supply lines and possible electrical components for the LEDs fitted thereto.

The carrier can then be, at least in sections, in the form of a straight or bent rod.

For the spatial, in particular homogeneous, light emission, the carrier is preferably configured as a carrier in the form of a round rod. The cross section thereof perpendicular to the longitudinal axis can, for example, have a round or oval surface contour.

In order for the LEDs to be held particularly securely and especially flat, it may also be preferred, however, if the carrier is configured as a carrier in the form of a cant rod, for example, with a surface contour which is polygonal in cross section perpendicular to the longitudinal axis, for example, rectangular, hexagonal or octagonal. The LEDs then preferably rest on or over the flat segments of the carrier.

In order to apply the light-emitting diodes in a simple manner and to arrange them in a flexible manner, an LED lighting device is preferred in which the flexible substrate is a substrate in the form of a tape which is wound around the carrier.

It is particularly preferred if the LEDs are wound in helical fashion around the carrier, in particular with a constant pitch. In this case, the arrangement of the LEDs on the carrier can be controlled particularly easily, for example, by virtue of adjusting the size and/or shape of the outer circumference of the carrier, the pitch of the tape on the carrier and the LED density on the tape.

In order to produce a homogeneous luminous flux, an LED lighting device is preferred in which the LEDs are arranged at a uniform distance from one another in the longitudinal direction of the tape.

In order to produce a homogeneous luminous flux in a simple manner only in a sub-sector around the longitudinal axis, for example, in the range of 90° to 180°, the LEDs are arranged at the same distance from one another, merely in groups or in sections, in the longitudinal direction of the tape. That is to say, in particular, successive groups or sections of LEDs demonstrate the same LED arrangement pattern, but this pattern does not have a uniform distance between the LEDs. As a result, the tape can be wound onto the carrier in a simple manner and the LEDs can be concentrated in one or more angular sectors. This may be advantageous, for example, for use in surface luminaires.

In order to cool the LED lighting device it is preferred if the carrier is a tubular carrier. Then, the carrier which is heated as a result of the operation of the LEDs can be cooled by means of air being drawn through the tube interior. The air can be drawn passively (“chimney effect”) or actively.

In order to increase the cooling power, an LED lighting device is preferred in which at least one cooling rib is fitted on an inner wall of the tubular carrier, in particular a cooling rib which extends in the direction of the air being drawn (for example in a longitudinal direction). Preferably, a plurality of cooling ribs are provided.

In order to further increase the cooling power, an LED lighting device with active cooling is preferred. For this purpose, it is particularly preferred if the LED lighting device has a fan, for example, a blower, for blowing air through the cavity or interior of the carrier.

For effective heat dissipation and distribution, any material with good thermal conductivity can be used as the carrier (base) material, wherein a material with good thermal conductivity is understood to mean a material with a thermal conductivity λ of more than 10 W/(m·K), in particular of more than 100 W/(m·K), especially of more than 250 W/(m·K). Thus, for example, stainless steel, low alloy steel, brass, etc. can be used. However, it is particularly preferred if the carrier includes copper, aluminum or an alloy of copper, aluminum or both.

For simple fitting it is also preferred if the substrate is fastened on the carrier by means of an adhesive agent, in particular a double-sided adhesive tape or a liquid adhesive which then cures. Preferably, the curing adhesive cures during operation as a result of a development of heat.

It may be advantageous if a plurality of flexible substrates are arranged on one carrier. For example, a plurality of tapes can be wound parallel around a carrier, for example a plurality of tapes with in each case identically colored LEDs, but with differently colored LEDs between the tapes. Thus, for example, three tapes with the colors red, green and blue can be used. However, it is also possible for a plurality of chains of LEDs with a dedicated power supply line to be accommodated per tape, for example in an arrangement which is parallel to the longitudinal direction of the tape, for example, three chains of LEDs with the colors red, green and blue.

In order to achieve a high luminous efficacy, it may be preferred if the LEDs of a substrate include identically colored LEDs.

In order to allow the LED lighting device to illuminate in different colors, it may be preferred if the LEDs are color-adjustable. For this purpose, driver electronics which are arranged externally, or preferably on the carrier, can be provided, said driver electronics comprising a sequencer, for example.

Particular preference may be given to an LED lighting device in which the LEDs of a substrate include white LEDs, for example, with a blue LED chip with phosphor downstream which converts wavelength from blue to yellow, for example, using surface mounted technology, for example, using thin GaN technology. In this case, an LED or an LED module can also have a plurality of white individual chips, for example, on a common submount as a result of which it is likewise possible to achieve simple scaleability of the luminous flux.

It may be preferred if the LEDs of one or more substrates include differently colored LEDs. In this case, it is particularly preferred if the differently colored LEDs are combined to form clusters which can emit to form white mixed light, for example, in each case as an LED module on a common submount.

In general, organic LEDs (OLEDs) can be used instead of, or in addition to, inorganic light-emitting diodes, for example, on the basis of InGaN or AlInGaP.

Suitable optical elements can be connected downstream of the LEDs or LED groups (clusters), for example a scattering lens or a wide-angle lens, whose luminous flux maximum is not on its optical axis.

For large-area emission and/or emission with a high light intensity, it may be preferred if a plurality of LED lighting devices are combined to form a set (a group).

For simple installation and removal, the LED lighting devices are preferably connected to one another detachably.

In this case, it is in particular preferred if at least two LED lighting devices of the set are connected to one another detachably by means of a bayonet-type closure, wherein at least one flexible tape of one of the two LED lighting devices is connected electrically to at least one flexible tape of the other of the two LED lighting devices via an electrical connection unit, for example, a plug.

The LED luminaire has at least one such LED lighting device or at least one set of a plurality of combined such LED lighting devices.

In order to further homogenize the luminous flux, an LED luminaire is preferred in which the lighting devices are surrounded at least partially by a transparent light scattering device, for example a diffuser (scattering layer), for example a milk glass, or have such a device.

It is preferably possible to use the LED luminaire as a decorative luminaire, as a signaling luminaire in particular as a handheld signaling luminaire, or as a surface luminaire, for example a ceiling-mounted luminaire or a wall-mounted luminaire.

However, it is also possible for the LED luminaire to be accessible by foot, in particular for architectural applications. For this purpose, its inner diameter is configured to be correspondingly large.

The invention will be described schematically in more detail with respect to exemplary embodiments in the following figures. Identical or functionally identical elements can in this case be provided with the same reference numerals for better clarity.

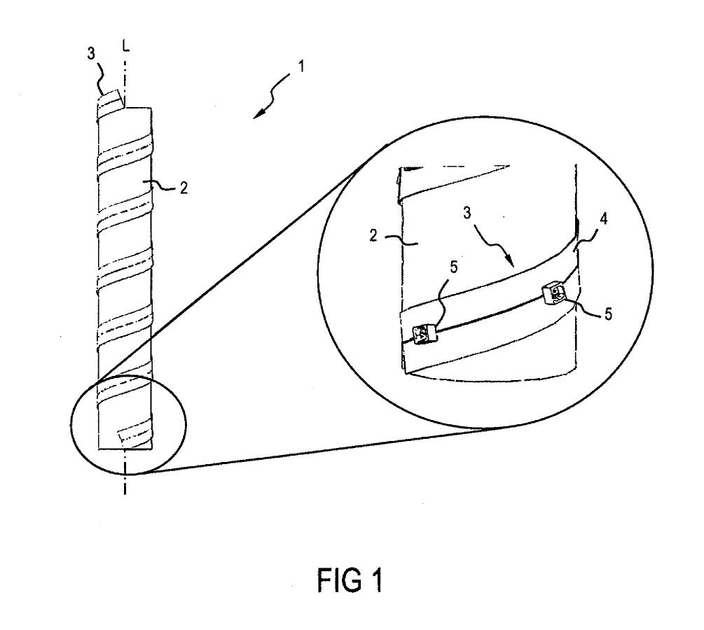

FIG. 1 shows a sketch in a side view of an LED lighting device and a detail thereof in an end region;

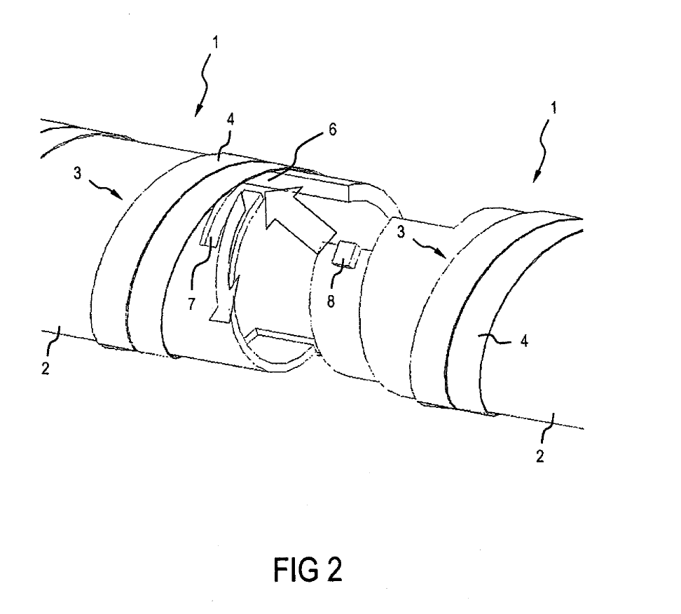

FIG. 2 shows, in an oblique view, two LED lighting devices to be connected in the connection region;

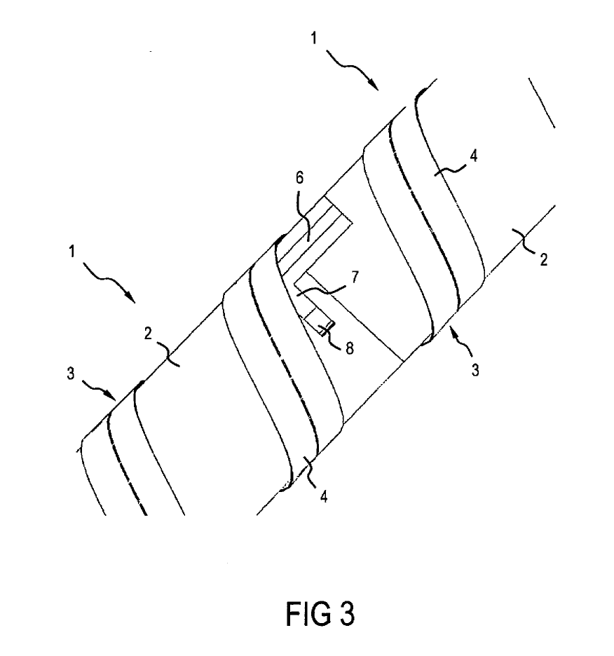

FIG. 3 shows, in a further oblique view, the two LED lighting devices, which are now connected, from FIG. 2 in the connection region;

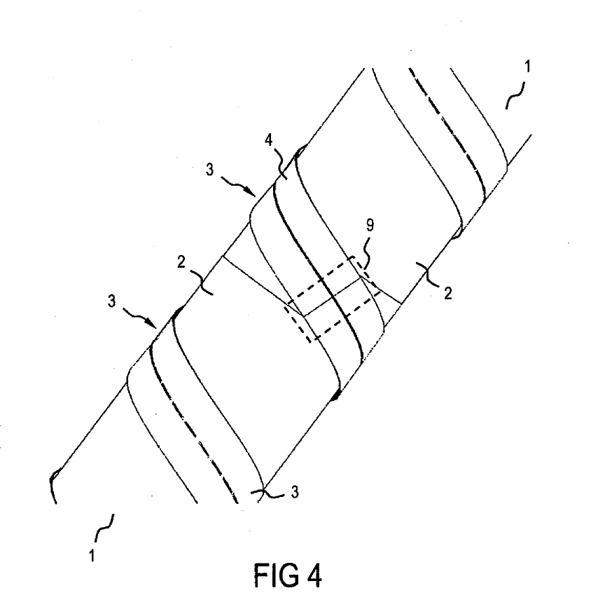

FIG. 4 shows, in yet a further oblique view, the connected LED lighting devices from FIG. 3 in the connection region with an electrical connection element;

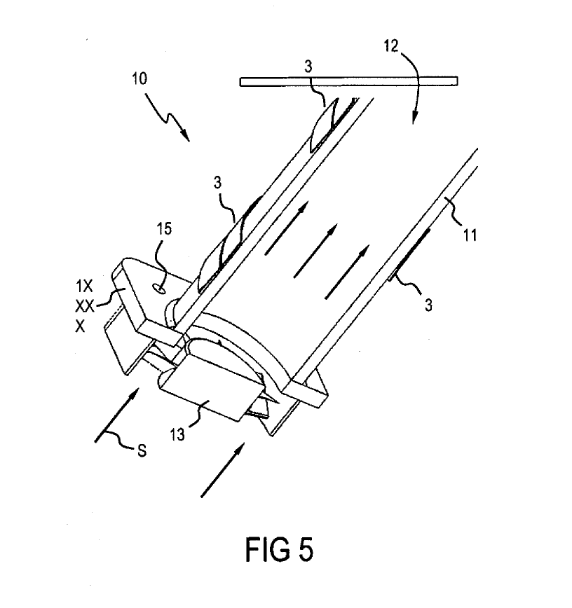

FIG. 5 shows a sectional illustration, in an oblique view, of an LED lighting device with a fan;

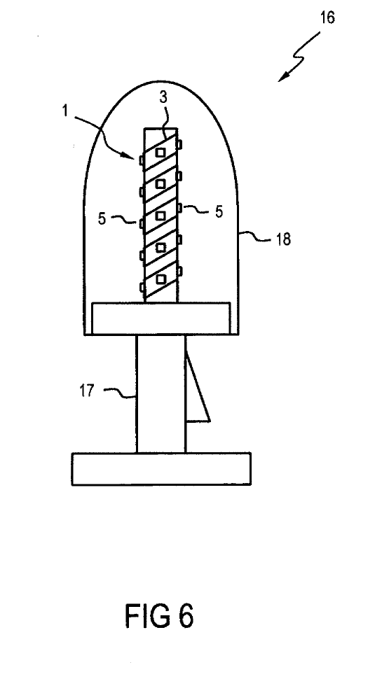

FIG. 6 shows a sketch, in a side view, of a table lamp with an LED lighting device;

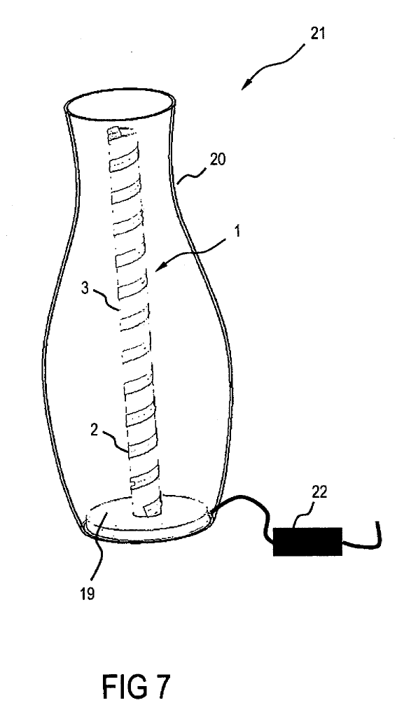

FIG. 7 shows a sketch, in a side view, of a decorative luminaire with an LED lighting device;

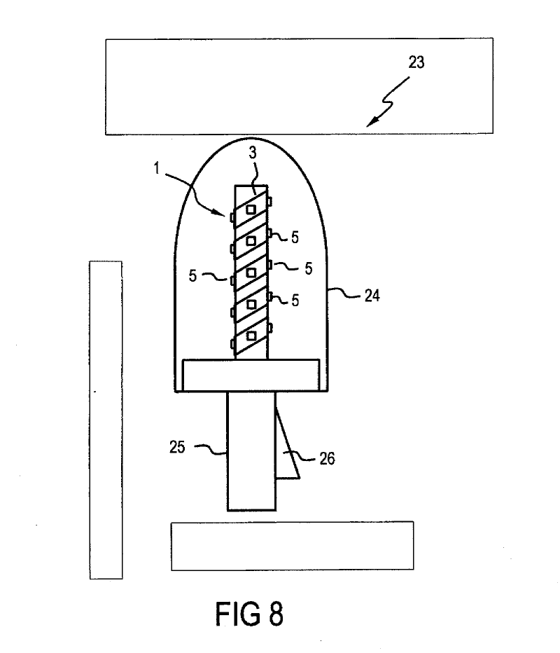

FIG. 8 shows a sketch, in a side view, of a signaling luminaire with an LED lighting device;

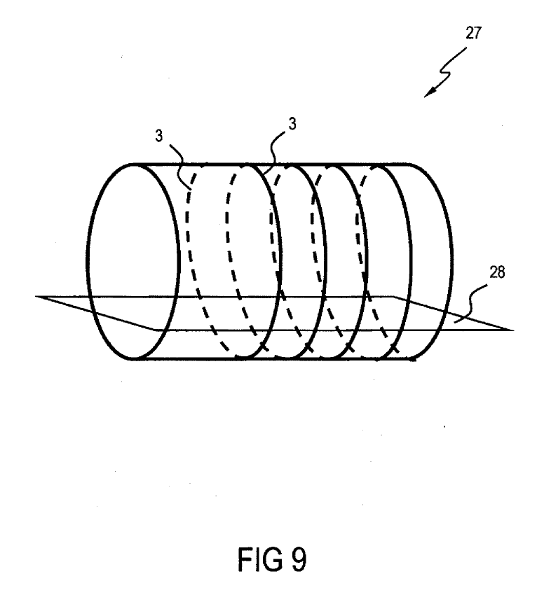

FIG. 9 shows a sketch, in an oblique view, of a pedestrian tunnel;

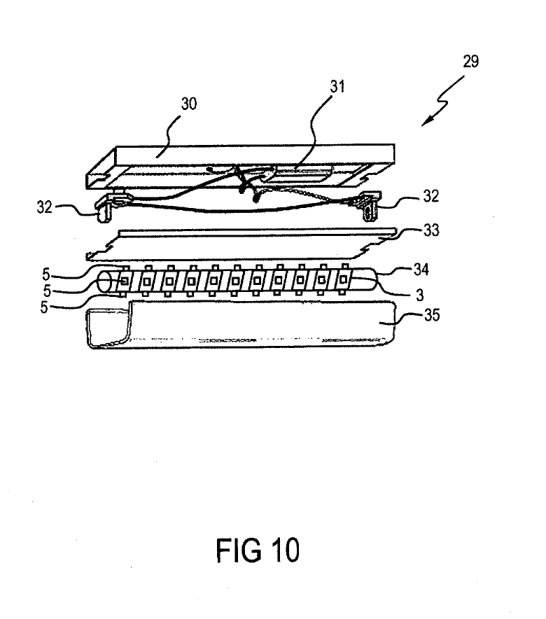

FIG. 10 shows an exploded illustration, in an oblique view, of a surface luminaire;

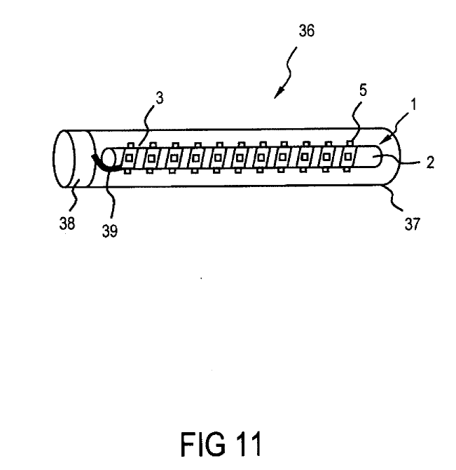

FIG. 11 shows an exploded illustration, in an oblique view, of a retrofit lamp with an LED lighting device.

FIG. 1 shows an LED lighting device 1 with a carrier 2 in the form of a round rod, an LED flextape 3 being wound in helical fashion around the outer surface of said carrier. As is shown in the detail in the circle on the right, the flextape 3 has a flexible substrate 3a in the form of a tape based on polyimide. Light-emitting diodes (LEDs) 5 are fitted at regular intervals in the longitudinal direction of the tape to that side of the flextape 3 which is remote from the carrier 2. The flextape 3 or the substrate 3a also has individual or a plurality of electrical lines and possibly electrical components for supplying power and for driving the LEDs fitted thereto, said electrical lines or electrical components not being illustrated here for reasons of improved clarity.

The light-emitting diodes 5 are arranged in such a way that their optical axis corresponds to the normal vector of the outer surface lying therebeneath of the carrier 2. The light-emitting diodes 5 are in this case in the form of light-emitting diodes which emit white light and can have one or more optical elements to form the luminous flux (not depicted).

This LED lighting device 1 can be produced in a simple manner, provides a highly homogeneous light distribution around the longitudinal axis L of the carrier 2 and can be matched easily to desired requirements, for example with respect to luminous intensity, homogeneity of the luminous flux or emission characteristic. For example, the luminous intensity can be adjusted simply by the pitch of the helix of the tape-shaped substrate 3 and/or by the diameter of the carrier 2. It is also possible for the light intensity to be increased by decreasing the distances between the light-emitting diodes 5. By virtue of suitable, uneven distances between the light-emitting diodes 5, it is also possible to achieve an emission characteristic of the LED lighting device 1 which is inhomogeneous specifically with respect to the angular distribution around the longitudinal axis L. The flextape 3 is fastened on the carrier 2 by means of an adhesive agent in the form of a self-curing adhesive.

The power supply to the LEDs 5 can be provided by means of a power supply system or a rechargeable battery, which are not illustrated here for improved clarity. Driver electronics for driving the LEDs 5 can be integrated on or in the carrier 2 or arranged externally, for example, in or on a power supply unit (not depicted).

In this case, the electrical line is designed to have a plurality of conductors, with the LEDs 5 being connected in parallel with one another between the individual supply lines or conductors. This means that open ends for power supply do not need to be treated any further. Particularly in the case of multicolored LEDs (in particular LEDs with a plurality of individually drivable, differently colored LED chips), more than two conductors can be used, for example in each case one conductor per color and a common ground conductor. Alternatively, the LEDs or LEDs of the same color can also be connected in series, however, in which case a suitable electrical link to the power supply needs to be ensured at an LED lighting device 1 acting as individual piece or end piece, for example, by connection of the open end of the conductors equipped with the LEDs to a conductor returning to the power supply or by connecting the conductors equipped with the LEDs to a carrier acting as ground.

In an alternative embodiment, differently colored LEDs can also be used instead of the white LEDs 5. In this case, it is possible, inter alia, to use color-adjustable LEDs or a plurality of groups of LEDs, in which the light-emitting diodes of different groups emit light in a different color. As a result, the color emitted by the LED lighting device can be changed. In this case, a sequencer (or another control device) for producing these color effects by suitable driving of the light-emitting diodes can be provided in a manner in which it is external or is integrated on or in the carrier 2. For example, it is generally possible to fasten more than one flexible substrate on the carrier 2. For color control of the LED lighting device, it may be expedient, for example, to wind at least three flextapes parallel around the carrier 2, with each tape having LEDs of a specific color (“LED chain”), preferably in colors which together can result in a white mixed light. It is thus possible for three flextapes with red, green and blue LEDs to be wound parallel on a carrier 2. A relative luminous intensity of the tapes can then be set in a very simple manner by a respective distance between the LEDs. If it is desired, for example, to compensate for a relatively low luminous intensity of a specific type of light-emitting diode, for example, the green light-emitting diodes, by virtue of an increased number or density, the green light-emitting diodes of the corresponding flextape are positioned correspondingly closer to one another. In general, the use of the flextape series LM XX by Osram is possible and preferred.

It is also possible to use, instead of an LED with an individual chip, an LED which has a cluster with a plurality of individual chips, which are particularly advantageously applied to one common submount. These individual chips can also have suitable colors, for example white or a combination of red, green and blue (possibly with an admixture of amber for producing a warm, white hue), in order to produce overall a white mixed light which is output by a downstream optical element which is common to the cluster. Provision can also naturally be made of an individual chip LED with one or more optical elements. The optical elements are then designed to achieve a homogeneous light distribution preferably in such a way that they “blur” or spread the luminous flux of the respective LED. For further homogenization of the luminous flux, it may also be suitable to assign a scattering element to each of the LEDs (for example a scattering film), or a scattering element, for example a frosted or opaquely transparent shroud, can be positioned around the LED lighting device 1 or a part thereof.

FIG. 2 shows a possibility for a detachable connection between two LED lighting devices 1 shown in FIG. 1 in the form of a bayonet-type closure in order to achieve a high degree of structural flexibility as a result of a modular design. For this purpose, each of the tubular carriers 2 has a longitudinal slot 6 at one end in a manner which is known in principle, with a short transverse slot 7 being set at right angles to the end of said longitudinal slot 6. At its other end, the carrier has a button 8, in a manner which is likewise known in principle, said button being inserted into the transverse slot 7 of the respective other carrier 2 to be connected. The arrows illustrate in the form of a sketch, the relative movement of the two carriers which is required for this purpose. The resultant set of LED lighting devices 1 can in principle be extended in any desired manner taking into consideration possible limit values, for example a power consumption or limit values for mechanical strength.

Alternatively it is also possible for a simple plug-type closure to be used, in which, in a similar manner to the bayonet-type closure, the outer diameter at one end of a tube corresponds to the inner diameter of the second tube, possibly with a fixing device. However, a screw-type closure can also be used, for example.

FIG. 3 shows the set of two LED lighting devices 1 shown in FIG. 2, in which the respective carriers 2 have now been coupled mechanically one inside the other via the bayonet-type closure.

FIG. 4 shows the two connected LED lighting devices 1 shown in FIG. 3, with a plug 9 being provided for electrically connecting the electrical lines of the respective substrates or flextapes 3. The plug 9 can be in the form of an appropriately sized so-called CONNECTSystem LM-XX Flex plug, for example, when using the LM XX Flextape series by Osram.

Apart from being used as a connector between two flextapes 3 (LM-CONN-10 Flex), a plug 9 can also be used as a feeder into the flextape 3 (for example LM-2PIN with 2 terminals for monochromatic LEDs or LM-4PIN with 4 terminals for RGB LEDs with three differently colored individual LED chips) and then coupled to the operating device (for example the power supply with driver electronics). In this case, installation without the use of tools is possible. For electrical coupling of a flextape or substrate, however, other connection methods can also be used, for example soldering or adhesive bonding with electrically conductive adhesive.

FIG. 5 shows a possibility for transporting heat away from an LED lighting device 10. For this purpose, the lighting device 10, as is already the case in FIGS. 1 to 4, equipped with a tubular carrier 11, which has a hollow interior 12 which extends over the length of the carrier 11 and is open at both ends. During operation of the LED lighting device 10, the light-emitting diodes (not depicted) are heated and thus also heat the carrier 11. The carrier 11 is produced from a material with good conductivity, in this case copper, for dissipating heat away from the light-emitting diodes and for good thermal distribution. The heating of the tube 11, in particular when the tube 11 is in a vertical or substantially vertical position, results in a chimney effect, in which the air heated by the tube 11 is dissipated upwards in the interior 12. In the exemplary embodiment shown, in order to intensify an air flow S through the interior 12, a fan 13 is positioned at the lower end of the carrier 11, said fan pushing cool ambient air into the interior 12 and thus achieving improved heat convection. The fan 13 is in this case fastened on a carrier 11 which is especially in the form of an end piece, the carrier terminating at one of its ends, in this case the lower end, with a foot or base 14. The foot 14 has corresponding fastening elements, in this case a screw hole 15 for receiving a screw connected to the fan 14. However, the LED lighting device is not restricted to such a fan fastening, but instead the fan can be fitted on the carrier, for example with a bayonet-type closure, in a manner similar to that shown in FIGS. 2 to 4, and it is also possible for other end pieces to be fitted to a uniform carrier via the bayonet-type closure, for example, a foot or base or other elements, for example a handle.

FIG. 6 shows a sketch of a standard lamp 16, in which an LED lighting device 1 is fastened in a lamp base 17 in a manner so as to stand vertically, for example by means of a bayonet-type closure, a plug-type closure or a screw-type closure. A power supply unit and driver electronics for the light-emitting diodes 5 of the LED lighting device 1 can also be accommodated in the base 17. In order to homogenize the light emitted by the LED lighting device 1, said lighting device is surrounded laterally and at the top by a dome-like, transparent and diffusely scattering covering shroud 18. The covering shroud 18 can consist of milk glass (opaque white glass) or frosted glass, for example.

FIG. 7 shows an LED lighting device 1, which is fastened perpendicularly on a base 19, the LED lighting device 1 being surrounded by a decorative element 20 in the form of a milky-white transparent vase-shaped body. The power supply to and driving of this decorative luminaire 21 is performed by a combined supply device 22 with power supply unit and driver electronics.

FIG. 8 shows a portable signaling luminaire 23, in which, in a manner similar to the luminaire shown in FIG. 6, a vertical LED lighting device 1 is covered by a milky-white, opaque covering shroud 24. A rechargeable battery (not depicted) for supplying power to the LEDs 5 of the LED lighting device 1 is located in a handle 25. The signaling luminaire 23 can be switched on and off by means of a switch 26. In addition, the color emitted by the LEDs 5 can be set on the signaling luminaire 23, either by corresponding actuation of the switch 26 or a further switch (not illustrated). For example, the luminaire 23 can be switched over between a milky-green light emission and a milky-red light emission. It is of course possible to set other colors or mixed colors, such as white.

FIG. 9 shows an embodiment of an LED device 27 used in the architectural sector. The LED lighting device is in turn in the form of a tube with an inner diameter which is sufficiently large to make it possible to gain access by foot to the LED lighting device 27. For this purpose, a walkway 28 is passed through the LED lighting device 27. The flextape 3 with the diodes fastened thereto (not depicted) is now arranged on the inner wall of the LED lighting device 27 in helical fashion. As a result, a corresponding tunnel lighting is provided. The flextape 3, of course, does not need to be arranged in helical fashion.

FIG. 10 shows a surface luminaire 29 (wall-mounted or ceiling-mounted luminaire) with a holder 30, a power supply unit 31 with integrated LED driver electronics, two end contacts 32, a cover plate 33, an LED lighting device 34 and a covering shroud 35. The LED lighting device 34 has contacts at the end (not illustrated) which are electrically connected to the electrical line of the LED lighting device. In this sense, the LED lighting device 34 can also be considered to be a double-ended tubular lamp. The light-emitting diodes 5 emit white (cold-white or warm-white) light. In the embodiment shown, the LEDs 5 are arranged substantially uniformly about the longitudinal axis of the LED lighting device 34; light emitted onto the plate 33 can be emitted outwards, for example, by being reflected by the milky-white cover 35. However, it is also possible to set the distances between the light-emitting diodes 5 in such a way that they are arranged substantially laterally and downwards, but not upwards in the direction of the plate 33. This results in an increased luminous efficacy of the ceiling-mounted luminaire or wall-mounted luminaire 29. Alternatively, the LED lighting device can also have contacts only on one side, however, in which case preferably a plurality of terminals are provided there.

FIG. 11 shows an LED fluorescent tube retrofit lamp 36 with the LED lighting device 1. In this case, the LED lighting device 1 is surrounded by a light-scattering, transparent diffuser tube or diffuser shroud 37. As a result, the light emission is homogenized further still. The electrical contacts 38 are only provided at one of the two ends, for example with two terminals for individual chip LEDs, or for example four terminals for RGB multiple LEDs. For installation in a conventional fluorescent tube housing, the lamp 36 is equipped with an operating device integrated therein (not illustrated here).

The present invention is of course not restricted to the embodiments shown. For example, a plurality of flextapes can be used in one arrangement instead of a helical winding, in which arrangement these flextapes are arranged so as to be spaced apart parallel to one another and in linear fashion in the longitudinal direction of the carrier; however, this is not preferred owing to the increased amount of complexity in terms of connections.

### LIST OF REFERENCE SYMBOLS

1 LED lighting device
2 Carrier
3 Flextape
4 Substrate
5 Light-emitting diode
6 Longitudinal slot
7 Transverse slot
8 Button
9 Plug
10 LED lighting device
11 Carrier
12 Interior
13 Fan
14 Base
15 Screw hole
16 Standard lamp
17 Lamp base
18 Covering shroud
19 Base
20 Decorative element
21 Decorative luminaire
22 Supply device
23 Signaling luminaire
24 Cover shroud
25 Handle
26 Switch
27 LED device
28 Walkway
29 Ceiling-mounted luminaire
30 Holder
31 Power supply unit
32 End contact
33 Plate
34 LED lighting device
35 Cover
36 LED lamp
37 Diffuser shroud
38 Electrical contact
39 Wire
L Longitudinal axis
S Air flow

1. A light-emitting diode lighting device, comprising:
a plurality of light-emitting diodes fastened on a flexible substrate, the flexible substrate being applied on a surface of a rod-shaped carrier.

2. The light-emitting diode lighting device as claimed in claim 1,
wherein the carrier is a carrier in the form of a round rod or a carrier in the form of a cant rod.

3. The light-emitting diode lighting device as claimed in claim 1,
wherein the flexible substrate is a substrate in the form of a tape which is wound around the carrier.

4. The light-emitting diode lighting device as claimed in claim 3,
wherein the light-emitting diodes are wound in helical fashion around the carrier with a constant pitch.

5. (canceled)

6. The light-emitting diode lighting device as claimed in claim 4,
wherein the light-emitting diodes are arranged at the same distance from one another, merely group wise, in the longitudinal direction of the substrate in the form of a tape.

7. The light-emitting diode lighting device as claimed in claim 1,
wherein the carrier is a tubular carrier, and in which at least one cooling rib is fitted to an inner wall of the tubular carrier.

8. (canceled)

9. The light-emitting diode lighting device as claimed in claim 7, further comprising:
a fan for blowing air through the cavity of the carrier.

10. (canceled)

11. (canceled)

12. (canceled)

13. The light-emitting diode lighting device as claimed in claim 1,
wherein a plurality of flexible substrates are arranged on a carrier.

14. The light-emitting diode lighting device as claimed in claim 13,
wherein in each case identically colored light-emitting diodes are fastened on the plurality of flexible substrates, but differently colored light-emitting diodes are fastened on different substrates.

15. The light-emitting diode lighting device as claimed in claim 1,
wherein the light-emitting diodes of a substrate comprise identically colored light-emitting diodes, it being possible for the light-emitting diodes of a substrate to be color-adjustable.

16. (canceled)

17. The light-emitting diode lighting device as claimed in claim 1,
wherein light-emitting diodes of a substrate comprise differently colored light-emitting diodes, which are combined to form clusters which can emit to give white mixed light.

18. (canceled)

19. The light-emitting diode lighting device as claimed in claim 1,
wherein driver electronics for the light-emitting diodes are fitted on the carrier.

20. A set of a plurality of combined light-emitting diode lighting devices, each light-emitting diode lighting device comprising:
a plurality of light-emitting diodes fastened on a flexible substrate, the flexible substrate being applied on a surface of a rod-shaped carrier.

21. The set as claimed in claim 20,
wherein the light-emitting diode lighting devices are connected to one another detachably.

22. The set as claimed in claim 21,
wherein two light-emitting diode lighting devices are connected to one another detachably by means of a bayonet-type closure or plug-type closure, at least the light-emitting diodes of a substrate of one of the two light-emitting diode lighting devices being connected electrically to at least the light-emitting diodes of a substrate of the other of the two light-emitting diode lighting devices via an electrical connection structure.

23. A light-emitting diode luminaire, comprising:
at least one light-emitting diode lighting device, comprising:
a plurality of light-emitting diodes fastened on a flexible substrate, the flexible substrate being applied on a surface of a rod-shaped carrier or a set of a plurality of combined light-emitting diode lighting devices, wherein each light-emitting diode lighting device comprises a plurality of light-emitting diodes fastened on a flexible substrate, the flexible substrate being applied on a surface of a rod-shaped carrier.

24. (canceled)

25. (canceled)

26. The light-emitting diode luminaire as claimed in claim 23,
which is configured to be in the form of a signaling luminaire.

27. The light-emitting diode luminaire as claimed in claim 23,
which is configured to be in the form of a surface luminaire.

28. The light-emitting diode luminaire as claimed in claim 23,
which is configured to be accessible by foot.

29. The light-emitting diode luminaire as claimed in claim 1,
wherein a plurality of flexible substrates are arranged so as to run parallel on the carrier.
